(19) United States
(12) Patent Application Publication
(10) Pub. No.: US 2015/0014640 A1
(43) Pub. Date: Jan. 15, 2015

(54) ORGANIC LIGHT EMITTING DIODE DISPLAY AND MANUFACTURING METHOD THEREOF

(71) Applicant: Samsung Display Co., Ltd., Yongin-city (KR)

(72) Inventor: Jung-Hyun SON, Yongin-city (KR)

(73) Assignee: Samsung Display Co., Ltd., Yongin-City (KR)

(21) Appl. No.: 14/106,024

(22) Filed: Dec. 13, 2013

(30) Foreign Application Priority Data
Jul. 9, 2013 (KR) 10-2013-0080550

(51) Int. Cl. H01L 51/52; H01L 51/56

(52) U.S. Cl. CPC H01L 51/5256; H01L 51/56
USPC 257/40; 438/28

(57) ABSTRACT

An OLED display includes a substrate, an organic light emitting element formed on the substrate, and an encapsulation body formed on the organic light emitting element, and the encapsulation body includes a first structure having a receiving portion and a second structure having thermal conductivity and received in the receiving portion.

### CROSS-REFERENCE TO RELATED APPLICATION

This application claims priority from and the benefit of Korean Patent Application No. 10-2013-0080550, filed on Jul. 9, 2013, which is hereby incorporated for all purposes as if fully set forth herein.

### BACKGROUND

1. Field

Exemplary embodiments of the described technology relate to an organic light emitting diode (OLED) display. More particularly, the illustrated embodiments relate to an encapsulation structure of an organic light emitting element.

2. Description of the Background

An organic light emitting diode (OLED) display is generally formed by forming a plurality of organic light emitting elements on a substrate. In this process, a function of the organic light emitting element may be deteriorated when organic light emitting elements are exposed to an external environment such as moisture or oxygen. Therefore, the organic light emitting element is sealed by an encapsulation body to prevent functional deterioration. As an encapsulation body, a glass substrate or a metal sheet may be applied.

The above information disclosed in this Background section is only to set up Applicant's recognition of problems within existing art and merely for enhancement of understanding of the background of the invention based on the identified source of problems, and therefore the above information cannot be used as prior art in determining obviousness into the present invention.

### SUMMARY

Exemplary embodiments of the present invention provide an organic light emitting diode (OLED) display including an encapsulation body of an organic light emitting element that can make a slim OLED display without affecting the organic light emitting element.

Additional features of the invention will be set forth in the description which follows, and in part will be apparent from the description, or may be learned by practice of the invention.

Still other aspects, features, and advantages of the present invention are readily apparent from the following detailed description, simply by illustrating a number of particular embodiments and implementations, including the best mode contemplated for carrying out the present invention. The present invention is also capable of other and different embodiments, and is its several details can be modified in various obvious respects, all without departing from the spirit and scope of the present invention. Accordingly, the drawing and description are to be regarded as illustrative in nature, and not as restrictive.

Exemplary embodiments of the present invention disclose an organic light emitting diode (OLED) display. The display includes a substrate. The display includes an organic light emitting element formed on the substrate. The display includes an encapsulation body formed on the organic light emitting element. The encapsulation body includes a first structure including a receiving portion. The encapsulation body also includes a second structure comprising thermal conductivity and provided in the receiving portion.

Exemplary embodiments of the present invention disclose a method for manufacturing of an organic light emitting diode (OLED) display. The method includes providing a first structure comprising a plurality of receiving portions. The method includes providing a second structure comprising thermally conductive members in the plurality of receiving portions. The method also includes combining the first structure and the second structure, wherein the combined structure covers the organic light emitting element on a substrate.

Exemplary embodiments of the present invention disclose a display. The display includes a layer of organic light emitting element disposed between electrodes comprising an anode, cathode and a substrate. The display includes an encapsulation body including a first structure and a second structure. The first structure comprising a plurality of receiving portions. The second structure including thermally conductive members in the plurality of receiving portions. The first structure is combined to the second structure, wherein the combined structure is configured to cover the organic light emitting element on a substrate.

It is to be understood that both the foregoing general description and the following detailed description are exemplary and explanatory and are intended to provide further explanation of the invention as claimed.

### BRIEF DESCRIPTION OF THE DRAWINGS

FIG. 1 is a cross-sectional side view of an organic light emitting diode (OLED) display according to a first exemplary embodiment.

FIG. 2 to FIG. 5 are cross-sectional views for illustrating a manufacturing process of an encapsulation body of the OLED display according to the first exemplary embodiment.

FIG. 6 is a bottom view of the encapsulation body of the OLED display according to exemplary embodiments.

FIG. 7 to FIG. 9 are cross-sectional views for illustrating a manufacturing process of an encapsulation body of an OLED display according to a second exemplary embodiment.

FIG. 10 is a cross-sectional side view of the OLED display according to the second exemplary embodiment.

FIG. 11 is a bottom view of a first structure of an encapsulation body according to a third exemplary embodiment.

FIG. 12 is a top plan view of a second structure of an encapsulation body io according to a third exemplary embodiment.

FIG. 13 is a bottom view of a first structure of an encapsulation body according to a fourth exemplary embodiment.

FIG. 14 is a top plan view of an encapsulation body according to a fourth exemplary embodiment.

FIG. 15 is a cross-sectional side view of an OLED display according to a fifth exemplary embodiment.

### DETAILED DESCRIPTION OF THE ILLUSTRATED EMBODIMENTS

An organic light emitting diode (OLED) and method for making an organic light emitting diode (OLED) are disclosed. In the following description, for the purposes of explanation, numerous specific details are set forth in order to provide a thorough understanding of the present invention. It is apparent, however, to one skilled in the art that the present invention may be practiced without these specific details or with an equivalent arrangement. In other instances, well-known structures and devices are shown in block diagram form in order to avoid unnecessarily obscuring the present invention.

Exemplary embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

The drawings and description are to be regarded as illustrative in nature and not restrictive, and like reference numerals designate like elements throughout the specification. The size and thickness of the components shown in the drawings are optionally determined for better understanding and ease of description, and the present invention is not limited to the examples shown in the drawings.

It will be understood that when an element such as a layer, film, region, or substrate is referred to as being “on” another element, it can be directly on the other element or intervening elements may also be present.

It will be understood that for the purposes of this disclosure, “at least one of X, Y, and Z” can be construed as X only, Y only, Z only, or any combination of two or more items X, Y, and Z (e.g., XYZ, XYY, YZ, ZZ).

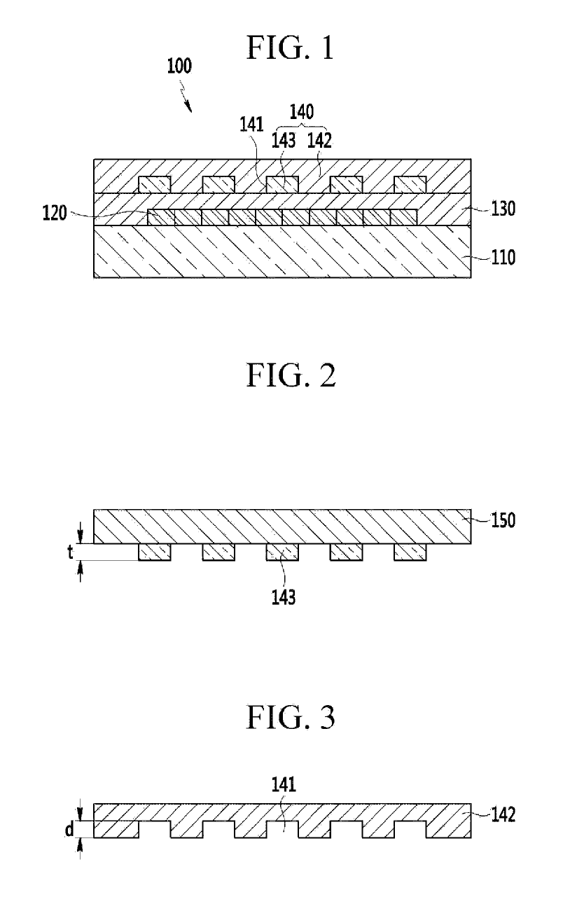

Hereinafter, an organic light emitting diode (OLED) display 100 according to a first exemplary embodiment will be described with reference to FIG. 1 to FIG. 6.

FIG. 1 is a cross-sectional view of the OLED display 100 according to the first exemplary embodiment.

As shown in FIG. 1, for example, the OLED display may include a substrate 110, an organic light emitting element 120 formed on the substrate 110, an adhesive layer 130 formed on the organic light emitting element 120, and an encapsulation body 140 formed on the adhesive layer 130.

The encapsulation body 140 is provided to protect the organic light emitting s element 120 from external environment such as moisture or oxygen by covering the organic light emitting element 120. For example, the encapsulation body 140 may be formed of a first structure 142 having a receiving portion 141, and a second structure 143 having thermal conductivity provided in the receiving portion 141.

In some examples, the substrate 110 may be formed of a transparent insulating substrate made of at least one of glass, quartz, and ceramic, or may be formed of a plastic substrate. The substrate 110 may include a display area for displaying an image and a non-display area formed at an external side of the display area. The non-display area may be divided into a sealing area and a pad area.

The adhesive layer 130 fixes the encapsulation body 140 to the substrate 110, and may be large enough to cover the display area and the sealing area. Therefore, the pad area of the substrate 110 may be exposed to the outside by a predetermined width rather than being overlapped with the adhesive layer 130.

For example, a driving circuit (not shown) may be formed on the substrate 110. The driving circuit is formed of circuit elements, each including a plurality of thin film transistors and a capacitor, and drives the organic light emitting element 120 by being electrically connected thereto.

The organic light emitting element 120 emits light according to a driving signal received from the driving circuit. In this case, the organic light emitting element 120 may be divided into a light emission area where light is substantially emitted and a non-light emission area disposed at the periphery of the light emission area.

The structure of the organic light emitting element 120 and the driving circuit is not limited to the illustrated drawings, and may have various structures within a scope that can s be easily modified by a person skilled in the art according to a direction in which an image is displayed with light emitted from the organic light emitting element 120.

In order to suppress permeation of moisture or oxygen into an organic emission layer of the organic light emitting element 120, an upper portion of the organic light emitting element 120 is sealed by the encapsulation body 140. That is, the encapsulation body 130 is io disposed on the substrate 110 where the organic light emitting element 120 is formed so as to cover the organic light emitting element 120.

In order to minimize expansion during a thermal-curing process, the encapsulation body 140 may be formed by combining the first structure 142 having relatively high thermal conductivity and the second structure 143 having a relative low expansion is characteristic.

For example, the first structure 142 may be a highly thermally conductive metal, having relatively high thermal conductivity such as at least one of aluminum, copper, and silver.

The second structure 143 may be a low thermally expandable material, having a relatively low thermal expansion coefficient such as at least one of invar, tungsten, and silicon.

In the first exemplary embodiment, the first structure 142 and the second structure 143 are respectively made of aluminum and invar.

For example, FIG. 2 shows the second structure 143 before being combined with the first structure 142, and the second structure 143 may be formed by a punching method on a second member made of invar on a release film 150. Thus, the second structure 143 has a thickness t, and as shown in FIG. 6, the second structure 143 may have a lattice-shaped pattern, but the shape of the second structure 143 is not limited thereto.

For example, FIG. 3 shows the first structure 142 where the receiving portion 141 is formed in a first member made of aluminum, and the receiving portion 141 may be formed of cavity having a depth of d formed by half-etching. Here, the receiving portion 141 may have a lattice shape corresponding to the pattern of the second structure 143 so as to receive the second structure 143. Furthermore, the depth d of each receiving portion 141 may be equivalent to the thickness t of the second structure 143.

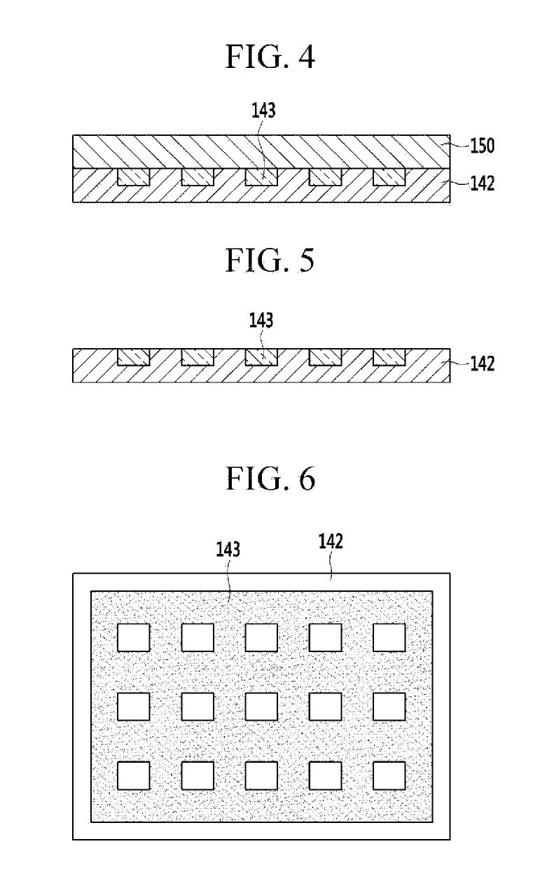

For example, FIG. 4 shows a shape of the second structure 143 combined in the receiving portions 141 of the first structure 142 before the release film 150 is released from the second structure 143. FIG. 5 shows the shape of the second structure 143 having the release film 150 of FIG. 4 removed from the second structure 143. That is, the release film 150 is removed from the second structure 143 after the second structure 143 is received in the receiving portion 141 of the first structure 142.

FIG. 6 shows a shape of combination of the first structure 142 and the second structure 143. For example, the shape of the receiving portion 141 formed in the first structure 142 and the shape of the second structure 143 are equivalent to each other for combination of the first structure 142 and the second structure 143.

In some examples, the first structure 142 and the second structure 143 may be combined to each other by an adhesive or an adhesive layer such as an adhesive film, or may be combined to each other by a method such as a surface treatment, heat treatment, or compression.

As described, the OLED display 100 including an encapsulation body 140 can suppress thermal expansion of the encapsulation body 140, particularly, the first structure 142, during a thermal-curing process performed in the manufacturing process. This is because that the second structure 143 received in the first structure 142 has a low thermal expansion characteristic so that thermal expansion of the first structure 142 can be suppressed.

Further, the combination structure of the first structure 142 and the second structure 143 combined with each other with a lattice-shaped pattern may improve a strength characteristic of the encapsulation body 140, and may also improve an impact-resistance characteristic of the OLED display 100 due to the combination structure of the first and second structure 142 and 143.

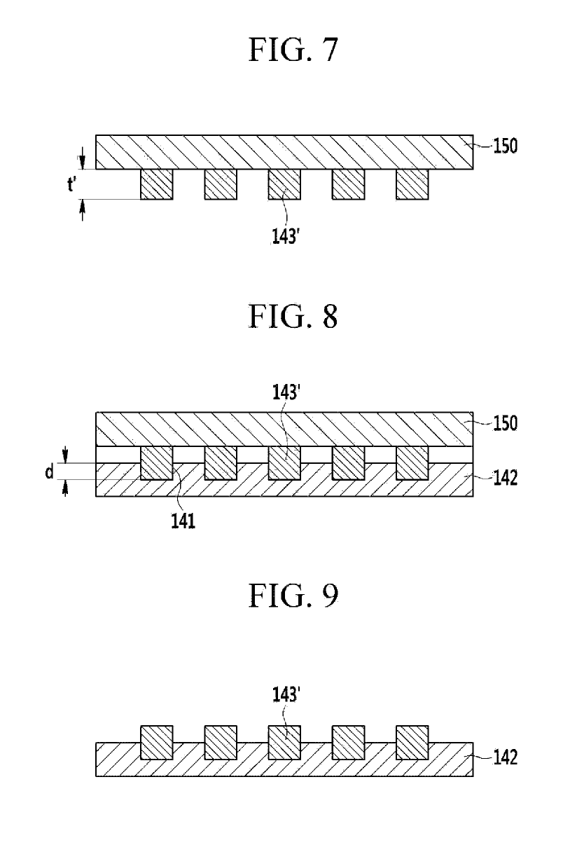

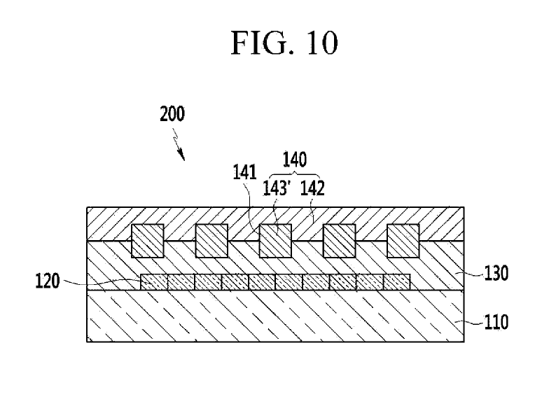

FIGS. 7 to FIG. 9 are provided for illustration of a manufacturing process of an encapsulation body of an OLED display according to a second exemplary embodiment. FIG. 10 is a cross-sectional side view of the OLED display according to the second exemplary embodiment.

As shown in FIG. 7, for example, a second structure 143′ formed on a release film 150 has a thickness t′, and the thickness t′ of each of the second structure 143′ of the second exemplary embodiment is larger than a depth d of receiving portions 141 of the first structure 142.

For example, FIG. 8 shows that the second structure 143′ is combined to the receiving portion of the first structure 142. FIG. 9 shows that the release film 150 is removed from the second structure 143′ after combination of the second structure 143′ and the first structure 142.

FIG. 10 is a cross-sectional side view of an OLED display 200 having an encapsulation body 140 that includes the first structure 142 and the second structure 143′, and a part of each of the second structure 143′ is protruded from the surface of the first structure 142. Therefore, when the encapsulation body 140 contacts an adhesive layer 130, a contact area can be increased so that adherence with the adhesive layer 130 can be further increased.

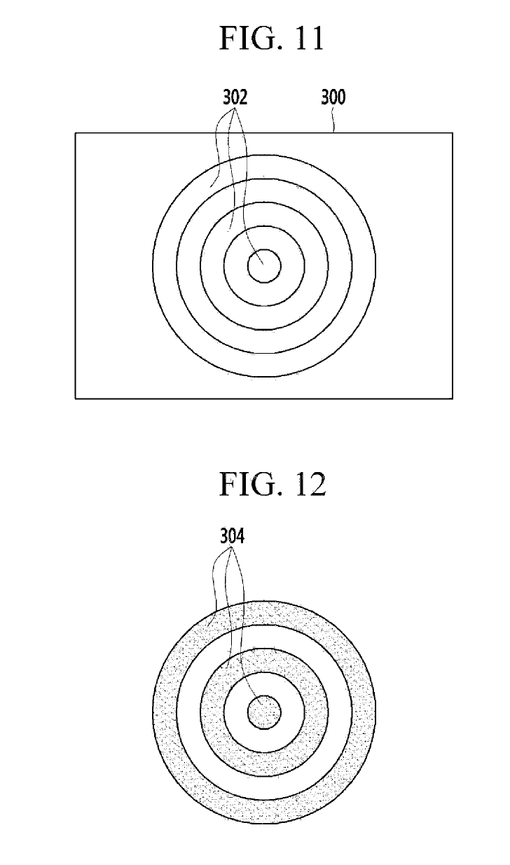

FIG. 11 and FIG. 12 respectively show a first structure 300 and second structure 304 of an encapsulation body according to a third exemplary embodiment, and the second structure 304 of the third exemplary embodiment may have a circular-shaped pattern. Thus, the first structure 300 is provided with receiving portions 302 having a circular-shaped pattern. The first structure 300 and the second structures 304 may be provided like the first and second structures 142 and 143 of FIG. 1, or alternatively, they may be provided like the first and second structures 142 and 143′of FIG. 10.

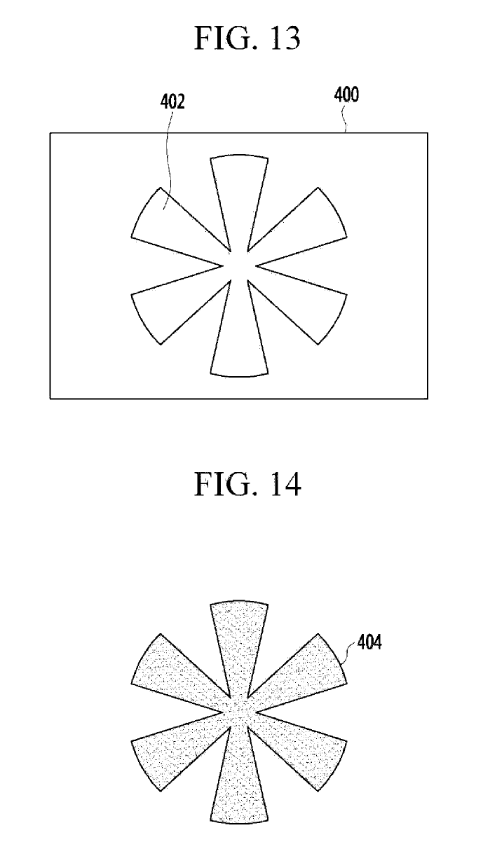

FIG. 13 and FIG. 14 respectively show a first structure 400 and a second structure 404 of an encapsulation body according to a fourth exemplary embodiment, and the second structure 404 of the fourth exemplary embodiment may have a radial-shaped pattern. Thus, the first structure 400 is provided with a receiving portion 402 having a radial-shaped pattern. The first structure 400 and the second structures 404 may be provided like the first and second structures 142 and 143 of FIG. 1, or alternatively, they may be provided like the first and second structures 142 and 143′of FIG. 10.

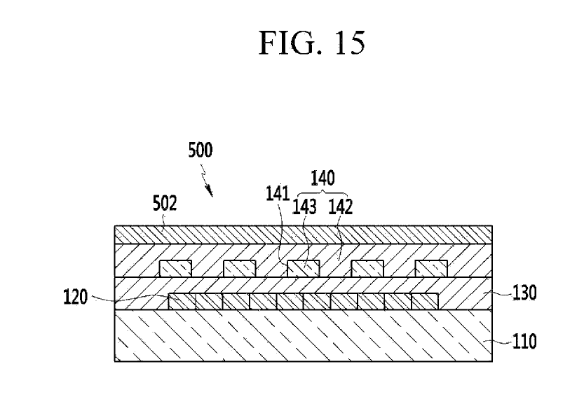

FIG. 15 is a cross-sectional side view of an OLED display 500 according to a fifth exemplary embodiment, and the OLED display 500 may further include a protection layer 502 disposed on a first structure 142 in addition to constituent elements of the OLED display of the first exemplary embodiment. The protection layer 502 may include polyethylene terephthalate (PET).

Table 1 shows comparison between Experimental Examples 1 and 2 where the encapsulation body of the present invention is applied and Comparative Examples 1, 2, 3, and 4. Experimental Examples 1 and 2 are the OLED displays of the first and fifth exemplary embodiments, the Comparative Example 1 is an OLED display of which an encapsulation body is formed of one aluminum layer, the Comparative Example 2 is an OLED display of which an encapsulation body is formed of a protection layer formed of one aluminum layer and a PET, the Comparative Example 3 is an OLED display of which an encapsulation body is formed of two aluminum layers, and the Comparative Example 4 is an OLED display of which an encapsulation body is formed as a protection layer formed of two aluminum layers and a PET.

TABLE 1

| | Experimental | Experimental | Comparative | Comparative | Comparative | Comparative |
|---|---|---|---|---|---|---|
| | Example 1 | Example 2 | Example 1 | Example 2 | Example 3 | Example 4 |
| Structure | Exemplary | Exemplary | single | single | double | double |
| of | Embodiment 1 | Embodiment 5 | aluminum | aluminum | aluminum | aluminum |
| encapsulation | | | layer | layer + PET | layer | layer + PET |
| body | | | | | | |
| Scratch- | 9H | 9H | 5H | 7H | 6H | 8H |
| resistance | | | | | | |
| Pressure | 90 kgf | 100 kgf | 50 kgf | 70 kgf | 60 kgf | 80 kgf |
| load | | | | | | |
| Point load | 20 kgf | 25 kgf | 5 kgf | 15 kgf | 10 kgf | 20 kgf |
| Thermal | 0.001% | 0.001% | 0.01% | 0.01% | 0.01% | 0.01% |
| expansion | | | | | | |
| rate | | | | | | |

As shown in Table 1, Experimental Examples 1 and 2 using the encapsulation body according to the present invention have high scratch resistance, high pressure load, and high point load on average compared to Comparative Examples 1, 2, 3, and 4, and have relatively low thermal expansion rates.

According to the exemplary embodiments, an encapsulation body where the first structure having high thermal conductivity and the second structure having a low thermal expansion characteristic are combined with each other and are used as an encapsulation substrate so that thermal expansion of the encapsulation substrate due to a thermal-curing process can be suppressed compared to a case in which only a metallic material is used as the encapsulation substrate. Prevention of deformation of the encapsulation substrate can prevent formation of an unnecessary space, and this may act as an important factor for realization of a slim OLED display.

In addition, strength of the encapsulation body can be reinforced according to a combination relationship between the first structure and the second structure, and accordingly, an impact-resistance characteristic of an OLED display having the combination relationship io between the first structure and the second structure can be effectively improved. Furthermore, heat generated in driving of the OLED display can be smoothly discharged to the outside due to the thermal conductivity of the first structure, and thus deterioration of the organic light emitting element due to heat can be prevented and the life-span of the display can be extended.

It will be apparent to those skilled in the art that various modifications and is variations can be made in the present invention without departing from the spirit or scope of the invention. Thus, it is intended that the present invention cover the modifications and variations of this invention provided they come within the scope of the appended claims and their equivalents.

What is claimed is:

1. An organic light emitting diode (OLED) display, comprising:
a substrate;
an organic light emitting element disposed on the substrate; and
an encapsulation body disposed on the organic light emitting element, the encapsulation body comprising:
a first structure comprising a receiving portion, and a second structure comprising thermal conductivity and disposed in the receiving portion.

2. The OLED display of claim 1, wherein the first structure comprises at least one of aluminum, copper, and silver.

3. The OLED display of claim 1, wherein the second structure comprises at least one of invar, tungsten, and silicon.

4. The OLED display of claim 1, wherein the second structure comprises a lattice-shaped pattern, a radial-shaped pattern, or a circular-shaped pattern.

5. The OLED display of claim 1, wherein the receiving portion is a cavity formed in the first structure.

6. The OLED display of claim 5, wherein the receiving portion has a lattice-shaped pattern, a radial-shaped pattern, or a circular-shaped pattern.

7. The OLED display of claim 1, further comprising:
an adhesive layer disposed between the first structure and the second structure.

8. The OLED display of claim 5, wherein the thickness of the second structure is greater than the depth of the cavity.

9. The OLED display of claim 1, wherein the encapsulation body further comprises a protection layer disposed on the first structure.

10. A method for manufacturing of an organic light emitting diode (OLED) display, the method comprising:
forming a first structure comprising a plurality of receiving portions;
disposing a second structure comprising thermally conductive members in the plurality of receiving portions; and
combining the first structure and the second structure, wherein the combined structure covers an organic light emitting element on a substrate.

11. The manufacturing method of the OLED display of claim 10, wherein the second structure is formed by a punching process.

12. The manufacturing method of the OLED display of claim 10, wherein the receiving portion is formed by a half-etching process.

13. The manufacturing method of the OLED display of claim 10, wherein the second structure is formed on a release film, and the release film is removed from the second structure after the second structure is disposed in the receiving portions.

14. A display, comprising:
an layer of organic light emitting layer disposed between an anode, and a cathode and on a substrate; and
an encapsulation body comprising a first structure and a second structure,
the first structure comprising a plurality of receiving portions, and
the second structure comprising thermally conductive members in the plurality of receiving portions, wherein
the first structure is combined to the second structure, and wherein
the combined structure is configured to cover the organic light emitting element on a substrate.

15. The display of claim 14, wherein the first structure comprises at least one of aluminum, copper, and silver.

16. The display of claim 14, wherein the second structure comprises at least one of invar, tungsten, and silicon.

17. An organic light emitting diode (OLED) display, comprising:
a substrate;
an organic light emitting element disposed on the substrate; and
an encapsulation body disposed on the substrate and encapsulating the organic light emitting element, the encapsulation body comprising at least one of aluminum, copper, and silver and at least one of invar, tungsten, and silicon at least partially embedded in the at least one of aluminum, copper, and silver.

18. The display of claim 17, wherein the at least one of aluminum, copper, and silver forms a first structure comprising a polygonal shape with protrusions, and the at least one of invar, tungsten, and silicon forms a second structure comprising a polygonal shape with holes such that the protrusions of the first structure are disposed in the holes of the second structure.

19. The display of claim 17, wherein the at least one of aluminum, copper, and silver forms a first structure comprising circular-shaped receiving portions, and the at least one of invar, tungsten, and silicon forms a second structure comprising circular-shaped patterns respectively disposed in the circular-shaped receiving portions of the second structure.

20. The display of claim 17, wherein the at least one of aluminum, copper, and silver forms a first structure comprising radial-shaped receiving portions, and the at least one of invar, tungsten, and silicon forms a second structure comprising radial-shaped patterns respectively disposed in the radial-shaped receiving portions of the second structure
